(19) United States
(12) Patent Application Publication
(10) Pub. No.: US 2006/0091388 A1
(43) Pub. Date: May 4, 2006

(54) Display device and method for manufacturing the same

(75) Inventor: Takeshi Kubota, Kumamoto (JP)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: MITSUBISHI DENKI KABUSHIKI KAISHA, Tokyo (JP)

(21) Appl. No.: 11/262,934

(22) Filed: Nov. 1, 2005

(30) Foreign Application Priority Data
Nov. 2, 2004 (JP) 2004-319150

(51) Int. Cl. G02F 1/136; H01L 29/04

(52) U.S. Cl. 257/59; 257/72; 349/42

(57) ABSTRACT

A display device including: a plurality of pixel lines each with a plurality of pixels; a pixel array consisting of said plurality of pixel lines; pixel transistors for driving said plurality of pixels; and a driving circuit for driving said plurality of pixel transistors, wherein: said plurality of pixel transistors include a plurality of predetermined pixel transistors; said driving circuit includes a first driving circuit for driving said predetermined pixel transistors, and a second driving circuit for driving other pixel transistors than said predetermined pixel transistors; and a difference in a threshold voltage among the respective predetermined pixel transistors ranges from 0.1 V to 0.5 V inclusive, and a difference in a threshold voltage between said predetermined pixel transistors and the other pixel transistors than said predetermined pixel transistors ranges from 0.5 V to 1.5 V inclusive.

### BACKGROUND OF THE INVENTION

1. Field of the Invention

This invention relates to a display device and a method for manufacturing the same.

2. Description of the Related Art

Conventionally, as regards a thin-film transistor using polysilicon, by using the method of melting an amorphous silicon film by heat by means of an excimer laser and thereafter crystallizing the molten film during cooling thereby to obtain polysilicon, development and manufacture of a low-temperature polysilicon thin film transistor have been carried out. According to this method, since a substrate itself does not almost suffer from the heat, the thin film transistors can be manufactured on a glass substrate with a low heat-resistance temperature. Further, using the thin film transistors as driving devices, a liquid crystal display device and organic EL display device have been developed and manufactured (for example, see JP-A-2002-341378).

As regards the silicon crystallized by the laser, in the region having a laser beam width irradiated with the laser through stage shifting, the silicon film is generally uniform in its crystallinity. However, since the width of a glass substrate actually used is larger than the above beam width, the entire surface of the substrate cannot be placed within the region of the laser beam width. For this reason, actually, after crystallization of a certain region has been completed by scanning the region of the laser beam width, laser scanning is newly started from the end of the substrate for the remaining region, thereby performing the crystallization of a new region of the laser beam width. In this case, since laser irradiation with neither overlapping nor gap between the old and new regions cannot be done, generally, the substrate surface is crystallized with permission of overlapping over a certain distance. However, in the vicinity of the overlapping zone, the crystallizing status of the silicon film differs from that in the other area. Thus, design is made so that the panel of a product does not extend over the above overlapping zone. In a practical display device, an area in the silicon film with uniform crystallinity has been employed within the region of the laser beam width.

Therefore, the display panel manufactured so as to be placed within the above area, an uniform image can be obtained in almost all cases so that the display device with no problem can be provided. However as the case may be, laser oscillation becomes unstable. The area irradiated during this unstable oscillation, i.e., only the area called “mis-shot” gives different crystallinity of the silicon film from the surroundings. This area will be visually recognized in display, which makes it impossible to complete the product. This led to reduction in the production yield.

Further, where manufacture of the display device with a larger display area than the region of the laser beam width is attempted, otherwise if design is made so that even with the display device with a small display area, a maximum number of panels can be taken from the interior plane of the glass substrate, it lies off the region of the laser beam width. In this case also, the overlapping zone which gives the different crystallinity from the surroundings is employed. Thus, this area is visually recognized in display, which made it impossible to complete a practical product. Thus, as regards the display device using the actual low temperature polysilicon thin film transistor, the panel having the size larger than the laser beam width cannot be actually manufactured. This was an obstruction for the production at low cost through effective use of the interior plane of the glass substrate.

### SUMMARY OF THE INVENTION

This invention has been accomplished to solve the problems described above. An object of this invention is to provide a display device which permits different threshold values of low-temperature polysilicon thin film transistors within a panel and can be manufactured at low cost, and a method for manufacturing the display device.

The display device according to this invention is a display device comprising a plurality of pixel lines each with a plurality of pixels; a pixel array consisting of the plurality of pixel lines; pixel transistors for driving the plurality of pixels; and a driving circuit for driving the plurality of pixel transistors, characterized in that the plurality of pixel transistors include a plurality of predetermined pixel transistors; the driving circuit includes a first driving circuit for driving the predetermined pixel transistors, and a second driving circuit for driving other pixel transistors than the predetermined pixel transistors; and a difference in a threshold voltage among the respective predetermined pixel transistors ranges from 0.1 V to 0.5 V inclusive, and a difference in a threshold voltage between the predetermined pixel transistors and the other pixel transistors than the predetermined pixel transistors ranges from 0.5 V to 1.5 V inclusive.

This invention permits display panels having a size larger than a laser beam width to be manufactured, which could not be realized hitherto, and permits them to be freely arranged with no waste on a glass substrate so that the number of display panels can be obtained. Further, this invention permits voltage threshold values of low-temperature polysilicon thin film transistors to be different, thereby realizing a display device with improved display quality at very high production yield and also greatly reducing the production cost itself.

### BRIEF DESCRIPTION OF THE DRAWINGS

These and other objects and advantages of this invention will become more fully apparent from the following detailed description taken with the accompanying drawings in which:

FIGS. 1A to 1C are sectional views showing the process for manufacturing a thin film transistor structure of a liquid crystal display device according to the first embodiment of this invention.

FIGS. 2A and 2B are views showing a laser annealing method of thin film transistors of the liquid crystal display device according to the first embodiment of this invention;

FIG. 3 is a view showing the relationship between a laser annealing method and Vth in thin film transistors of the liquid crystal display device according to the first embodiment of this invention;

FIG. 4 is a view showing the configurations of thin film transistors and a driving circuit in the liquid crystal display device according to the first embodiment of this invention;

FIG. 5 is a view showing the relationship between a laser annealing method and Vth and the configuration of a driving circuit in the liquid crystal display device according to the second embodiment of this invention; and

FIG. 6 is a schematic view for explaining a laser annealing apparatus for thin film transistors in the liquid crystal display device according to the first and second embodiments of this invention.

### DETAILED DESCRIPTION OF THE PREFERRED EMBODIMENTS

### Embodiment 1

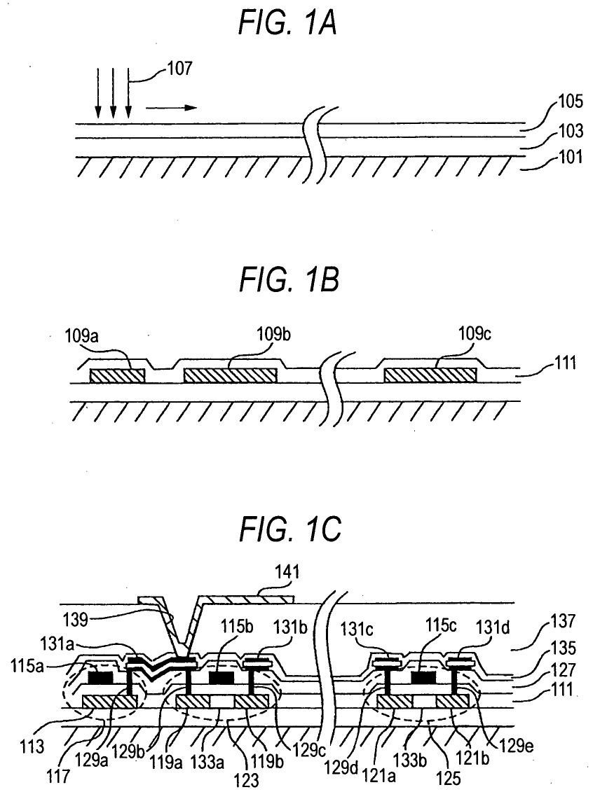

FIGS. 1A to 1C are sectional schematic views for explaining a method for manufacturing thin film transistors using a low-temperature polysilicon according to the first embodiment and a method for manufacturing a liquid crystal display device using the thin film transistors. Incidentally, in figures employed for the respective embodiments described below, the same or corresponding parts with like reference symbols will not be explained.

Referring to FIG. 1A, as regards a liquid crystal display device according to this embodiment, first, an underlying film 103 of a silicon oxide film having a thickness of 2500 Å is formed on a glass substrate 101 by e.g., PECVD (Plasma Enhanced Chemical Vapor Deposition). The underlying film 103 may be a stacked film such as a silicon nitride film and silicon oxide film. On the underlying film 103, an amorphous silicon film 105 having a thickness of 500 Å is formed. By annealing the amorphous silicon film 105 using a solid laser such as the YAG laser, a polysilicon film which serves as a p-type thin film field effect transistor and an n-type thin film field effect transistor is formed.

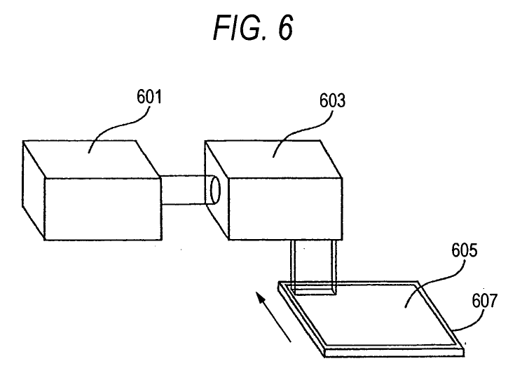

The laser used has a wavelength of λ=370 to 710 nm. As the solid laser, the YAG laser or YVO₄ laser is preferably used. The crystal doped with Nd ions or Yb ions is used. The solid laser is most preferably used which adopts, as pulse laser light, the second harmonic (wavelength of 532 nm) of Nd:YAG laser light (hereinafter referred to as YAG2ω), second harmonic (wavelength of 532 nm) of Nd:YVO₄ laser light, or second harmonic (wavelength of 515 nm) of Yb:YAG laser light. Referring to FIG. 6, as a technique of irradiating a glass substrate with a laser beam, a rectangular beam is continuously scanned on the entire surface of the substrate by moving a stage on which the substrate is mounted.

Referring to FIG. 1B, the polysilicon film formed as described above is processed by dry etching to form island-like polysilicon films 109a, 109b and 109c. An insulating film 111 which serves as a gate insulating film and a dielectric film of a capacitive electrode is further formed. This insulating film 111 may be a silicon oxide film formed using e.g., TEOS (TETRAETHOXY SILANE) PECVD. In this embodiment, the insulating film 111 has a thickness of 700 Å. Next, with the polysilicon films 109b and 109c being covered with a resist film, the polysilicon film 109a is implanted with phosphorus (P) ions which are n-type impurities, thereby forming a lower electrode.

Referring to FIG. 1C, a molybdenum alloy film is formed on the insulating film 111 by sputtering, and a part thereof is removed by patterning to form a common electrode 115a and gate electrodes 115b, 115c. In this way, a storage capacitor 117 is formed by the common electrode 115a, lower electrode 113 and insulating film 111. Thereafter, source/drain regions 119a, 119b are implanted with phosphorus ions serving as n-type conductivity impurities. Further, source/drain regions 121a, 121b are implanted with e.g., boron (B) ions serving as p-type conductivity impurities. Thus, a n-type thin film field effect transistor 123 and a p-type thin film field effect transistor 125 are formed. Next, on the common electrode 115a and gate electrodes 115b, 115c, a protection film 127 that is formed of a silicon oxide film having a thickness of 6000 Å made by TEOSCVD is formed. Thereafter, activation annealing is carried out at a heating temperature of 400° C. Further, first contact holes 129a to 129e are made in the protection film 127 and insulating film 111 by dry etching. Subsequently, a ternary film of a molybdenum film, an aluminum film and another molybdenum film is formed. The ternary film is etched to form electrodes 131a to 131d. And on the electrodes 131a to 131d, an insulating film 135 that is e.g., a silicon nitride film is formed and further a flattened film 137 is formed. In the flattened film 137, a second contact hole 139 is made by exposure development using photosensitive resin. A transparent conductor film is formed to extend from the inside of the second contact hole 139 onto the upper surface of the flattened film 137. The transparent conductor film is partially removed by etching to form a pixel electrode 141.

In a peripheral circuit area, the p-type thin film field effect transistor and the n-type thin film field effect transistor are formed by the technique described above. They are combined to construct a peripheral circuit. Further, a display pixel region, the n-type thin film field effect transistor is electrically connected to a transparent electrode separately formed, thereby form a display pixel. Further, a glass substrate on which these elements serving as semiconductor devices are formed is bonded to another glass substrate on which a color filter and opposite electrodes are formed. Liquid crystal is injected and sealed between these glass substrates. By performing the following steps inclusive of this step, a liquid crystal display device can be completed.

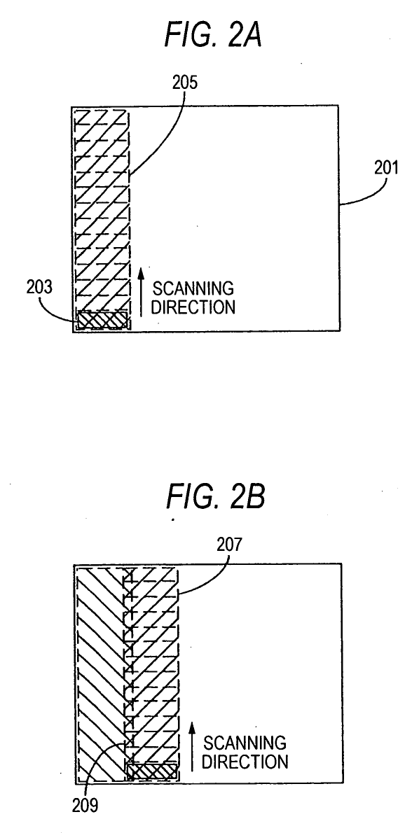

Referring to FIGS. 2A and 2B, an explanation will be given of the planar structure of a liquid crystal panel manufactured by the process described above. Target panels to be manufactured are effectively arranged on the glass substrate so that a larger number of panels can be obtained. A correct positional relationship between the panel to be completed and overlapping zone during laser annealing in the above explanation will be known. As an example, the explanation will be made on a certain single panel.

Referring to FIG. 2A, first, laser irradiation is done for the silicon in an anneal region A205 at a panel end. Laser irradiation is scanned in a source line direction on a pixel array. The source line direction refers to a direction perpendicular to the longer side of a laser beam. The anneal region A205 has a width corresponding to the longer side of the laser beam.

Referring to FIG. 2B, while permitting slight overlapping with the anneal region A205, the scanning is started from the panel end to complete the anneal for an anneal region B207 having the beam width. By repeating a necessary number of similar operations according to a substrate size, crystallization of the entire surface of the substrate is completed. An overlapping zone 209 exists between the anneal region A205 and anneal region B207.

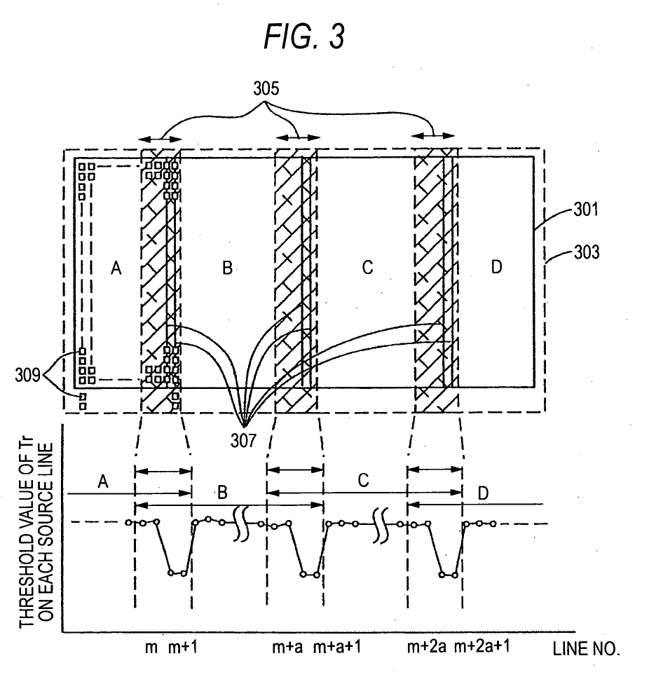

Referring to FIG. 3, the beam was scanned on a panel region 303 including a pixel region 301 with pixels arranged in an array so that four regions of anneal regions A to D and three overlapping zones 305 were eventually formed. Before actually designing the layout of the liquid crystal panel in the glass substrate, an evaluation was made for the test glass which permits transistor characteristic to be measured because only transistors are previously formed. This evaluation showed that a relationship of |Vth1−Vth2|<0.5 V is held about the threshold values Vth of any two transistors on a pixel line in parallel to the scanning direction of the laser irradiation. Further, as for the transistors at the overlapping zone between the anneal region A and anneal region B, between the threshold value Vth3 of the transistors on the two pixel lines and their extended lines in the source line direction on the side near the anneal region B within the overlapping zone and Vth1 of the transistors on other lines, there is a relationship |Vth1−Vth3|≧0.5 V. Conceptually, as shown in the graph of FIG. 3, only the transistors on two lines on the right side on the figure within each overlapping zone and their extended lines provide a lower threshold value Vth. Because it seems that the above data can be reproduced for the similar overlapping zones on the basis of these fundamental data, a dedicated liquid panel was designed in conformity with six lines in the three overlapping zones. Because the laser beam width is regenerated with no variation regardless with an apparatus used and the glass size is not changed, if the above fundamental data has been once obtained, the data with good reproducibility can be obtained. For this reason, it is not difficult to reflect the above data for designing of the liquid crystal panel.

Next, an explanation will be given of an example of a method for avoiding the problem in display for the liquid panel including the transistors with different Vth values.

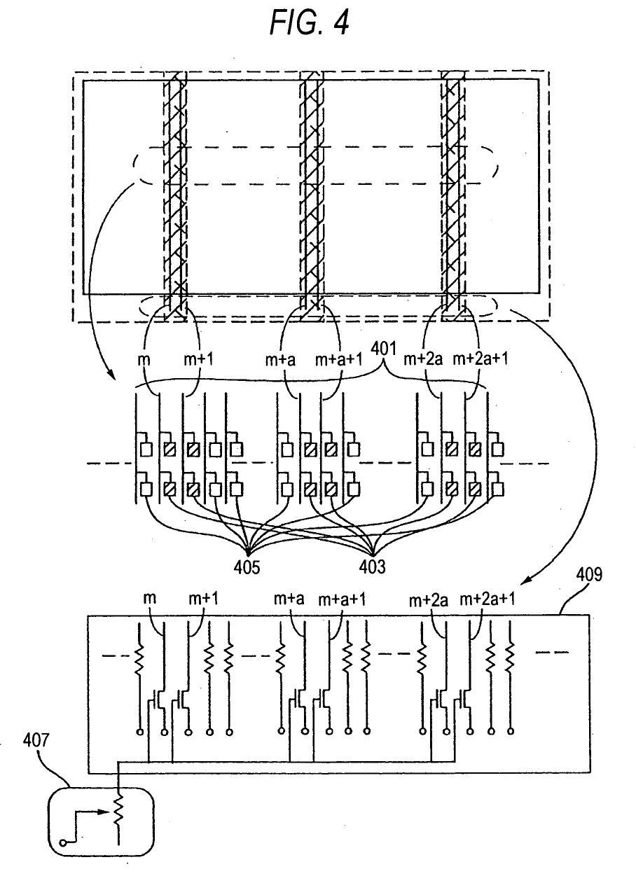

Referring to FIG. 4, the panel is arranged so that the overlapping zones are in parallel to the source lines. In the overlapping zones, the predetermined pixel transistors on the m-th, (m+1)-th, (m+a)-th, (m+a+1)-th, (m+2a)-th and (m+2a+1)-th source lines provide lower Vth values. In this way, the predetermined pixel lines having predetermined pixel transistors with different Vth values are adjacent plural lines and the laser beam width has a prescribed length. Therefore the above predetermined pixel lines are lines with a certain period which can be defined in such a sequence as described above. Since the predetermined pixel lines are periodically located, previous designing for dealing with them can be facilitated.

For these six source lines, pixel transistors 403 which are different from the transistors 405 on the source lines were employed. The Vth value influences the speed of charging and others to visually show differences in display. Therefore by adjusting the widths and lengths of the channels of the transistors, differences in Vth can be cancelled without adding a circuit for correction. Further, the same effect can be obtained by changing the shapes and materials of the transistors.

Further in this embodiment, the driving circuit connected to the predetermined pixel lines which is different from that connected to the other pixel lines was adopted. In FIG. 4, a single driving circuit 409 for driving each pixel line is shown. However, internally, the driving circuit connected to the predetermined pixel lines and that connected to the other pixel lines are separate driving circuit with different output impedances. Concretely, the source lines other than these predetermined pixel lines i.e., the six source lines are given a lengthened routing distance of an internal wiring to change their resistance. In order to change the resistance, the method of changing the substance on the way of manufacturing is effective. This technique permits the differences in Vth by simple design change for correction.

With only the above correction, the effect of making it difficult to visually recognize unevenness in display due to changes in Vth can be obtained. However since slight variations are generated in the degree of change in Vth, a structure capable of making invisible the remaining unevenness while watching a lighting status was adopted. Concretely, an adjusting circuit 407 was provided so that the transistors are connected to all the predetermined lines to adjust their resistance in an analog manner. By controlling the voltage applicable to the gate of each transistor not through the circuit on the liquid crystal glass but the simple adjusting circuit 407 with a variable resistance and a variable capacitor formed on a power board used for mounting, while watching a displayed image, the unevenness in display can be adjusted to a level not problematic in practical use.

In this embodiment, design was made so that the adjusting circuit is added to only the overlapping zones during laser irradiation, i.e., the predetermined pixel lines on which changes in Vth are predictable. By individually adding the same adjusting mechanism to all the lines, the display evenness can be adjusted to the level invisible in practical use for occurrence of the change in Vth on uncertain lines such as occurrence of “laser mis-shot”.

For the cases where the status of different Vth values is reproduced with good reproducibility for not on a certain line but a specific region, if the pixel transistors within the region are caused to have different shapes or materials from those of the transistors within the other regions, through the same effect as described above, the display unevenness can be adjusted to the level visually unrecognizable or difficult to recognize.

In this embodiment, the explanation was made on the arrangement of predetermined pixel transistors to be arranged at the overlapping zone. However, the transistors of the peripheral circuit such as the driving circuit may be arranged within the region where the transistors with different Vth values at the overlapping zone are generated. For a digital circuit section, it is not necessary to take the countermeasure in circuit as long as the differences in Vth are not the level to invert a digital signal. However for an analog circuit, it is possible to take the countermeasure of adding the circuit for previously compensating for the differences in Vth as in the pixel region or changing the configurations of the transistors. In this case, for the arrangement of the transistors in the peripheral circuit, they are not required to be arranged completely regularly as compared with the pixel transistors so that they may not be arranged in a region where generation of changes in Vth is predictable. In this case, it is not necessary to provide a redundant correction circuit, thereby permitting the area of the circuit region to be reduced.

Further, if the display device with a combination of the transistors which are difficult to visually recognize a specific region with different Vth value from the other region in display and satisfy the relationship of |Vth1−Vth2|≧0.5V can be manufactured by the other method than that proposed in this embodiment, the same effect as in this embodiment can be obtained.

In this embodiment, the explanation was made of the case where polysilicon was made by the YAG laser which can easily produce the polysilicon with a larger grain size. But the same effect can be obtained also in the case where the polysilicon was made by the excimer laser. Further, as an example of the transmissive liquid crystal display device, the liquid crystal display device with the pixel electrodes of ITO was explained. But this invention can be widely applied to the reflective liquid crystal display device with a reflecting electrode of Al, semi-transmissive liquid crystal display device with both properties and further an organic EL display device using thin film transistors of a silicon film crystallized by the same laser described above. In the case of the organic EL, in principle, unevenness is greatly visually recognized in the characteristics of the transistors within the pixels so that the greater effect can be obtained.

As described above, in accordance with the invention according to this embodiment, the panel is arranged so that the overlapping zones during laser irradiation in laser annealing are in parallel to source lines, thereby making it difficult visually recognize the display unevenness due to the changes in the threshold values of the thin film transistors within each of the overlapping zones.

### Embodiment 2

As described above, in the first embodiment, the panel was arranged so that the overlapping zones during laser irradiation in laser anneal are in parallel to source lines, thereby making it difficult visually recognize the display unevenness due to the changes in the threshold values of the thin film transistors within each of the overlapping zones. On the other hand, in this embodiment, the panel is arranged so that the overlapping zones during laser irradiation in laser annealing are in parallel to gate lines, thereby making it difficult visually recognize the display unevenness due to the changes in the threshold values of the thin film transistors within each of the overlapping zones.

An explanation will not be given of the method for manufacturing the thin film transistors using the low-temperature polysilicon according to the second embodiment and the method for manufacturing the liquid crystal display device using the same in their sectional structures because they are the same as in the first embodiment.

In this embodiment, in annealing the amorphous silicon film, the amorphous silicon film is annealed using the gas laser such as an excimer laser to form a polysilicon film serving as channels of the p-type thin film field effect transistor and the n-type thin film field effect transistor. The laser gas used was an Xe-Cl laser; the wavelength used was 308 nm; and the power used was suitably determined while monitoring the crystallizing status within a range of 200 to 500 mJ/cm². The method of laser irradiation on the glass substrate was to sequentially scan the beam over the entire substrate surface by moving the stage on which the substrate is placed.

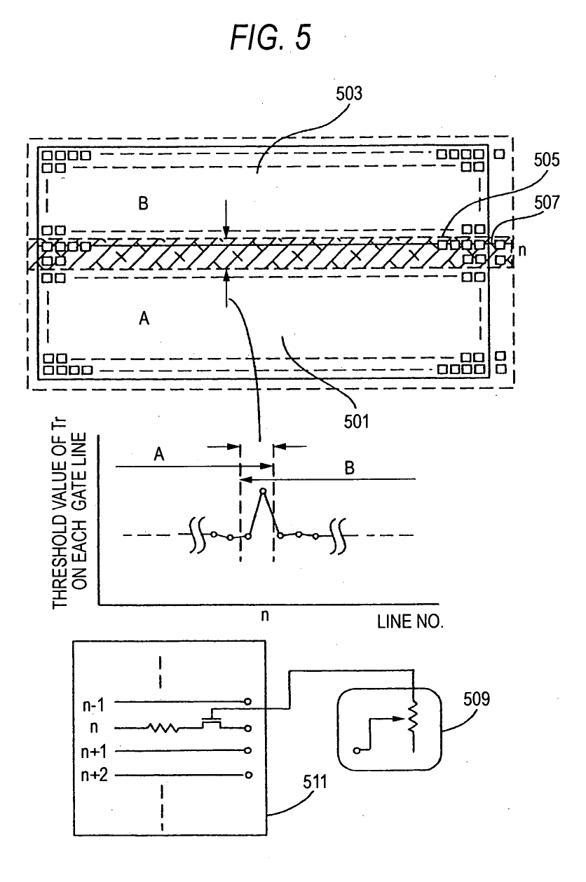

Referring to FIG. 5, first, laser irradiation is done continuously from one substrate end to another substrate end in a direction perpendicular to the longer side of a rectangular beam, thereby completing the annealing of an anneal region A501 having a width of the longer side of the beam.

Further, while permitting slight overlapping with the anneal region A501, the scanning is started from the substrate end to complete the anneal for an anneal region B503 having the beam width. By repeating a necessary number of similar operations according to a substrate size, crystallization of the entire surface of the substrate is completed. Subsequently, the liquid crystal display device is manufactured in the same process as in the first embodiment.

An explanation will be given of the planar structure of a liquid crystal panel according to the second embodiment. Target panels to be manufactured are effectively arranged on the glass substrate so that a larger number of panels can be obtained. A correct positional relationship between the panel to be completed and overlapping zone during laser annealing in the above explanation will be known. As an example, the explanation will be made on a certain single panel. As regards this single panel, as seen from FIG. 5, the laser irradiation was divisionally done for the anneal region A501 and anneal region B503. In this embodiment also, an overlapping zone 505 exists as in the first embodiment. The panel was arranged so that the long side direction of the overlapping zone 505 is in parallel to the gate lines.

In this embodiment also, as in the first embodiment, before actually designing the layout of the liquid panel in the glass substrate, an evaluation was made for the test glass which permits transistor characteristic to be measured because only transistors are previously formed. This evaluation showed that a relationship of |Vth1−Vth2|<0.5 V was held about the threshold values Vth of any two transistors in parallel to the overlapping zone 505. Further, as for the transistors at the overlapping zone 505 between the anneal region A501 and anneal region B503, between the threshold value Vth3 of the transistors on the one pixel line and its extended line in the gate line direction on the side near the anneal region B503 within the overlapping zone 505 and Vth1 of the transistors on other lines, there was a relationship |Vth1−Vth3|≧0.5 V. In this embodiment, the scanning direction of the laser annealing is done in parallel to the gate lines so that only the transistors on the one line on the upper side of overlapping zone 505 on the figure and its extended line provide a higher threshold value Vth. On the basis of these fundamental data, in this embodiment, a dedicated liquid panel was designed in conformity with the gate lines in which predetermined pixel transistors with great different Vth values are located.

Next, an explanation will be given of an example of a method for avoiding the problem in display for the liquid panel including the transistors with different Vt values. Now, it is assumed in FIG. 5 that the one line on which the predetermined pixel transistors different Vth values are located is referred to an n-th line. In this case, the driving circuit connected to the predetermined pixel lines which is different from that connected to the other lines was adopted. Concretely, a part of the driving circuit section on the line at issue is made of the ITO film used for the pixel electrode in place of an ordinary metallic wiring and the wiring structure partially bridged by the ITO film was newly adopted. Since the resistance of the ITO film is higher than the ordinary metallic film, the above design change means that of the resistance. In order to change the resistance, it is also effective to lengthen the routing length of the wiring as in the first embodiment. In this case, as in the first embodiment, simple design change for correction permits the differences in Vth to be cancelled.

With only the above correction, the effect of making it difficult to visually recognize unevenness in display due to changes in Vth can be obtained. However since slight variations are generated in the degree of change in Vth, a structure capable of making invisible the remaining display unevenness while watching a lighting status was adopted. Concretely, an adjusting circuit 509 was provided so that the transistor are connected to the specific line to adjust the resistance in an analog manner. By controlling the voltage applicable to the gate of each transistor not through the circuit on the liquid crystal glass but the simple adjusting circuit with a variable resistance and a variable capacitor formed on a power board used for mounting, while watching a displayed image, the display unevenness can be adjusted to a level not problematic in use.

In this embodiment, design was made so that the adjusting circuit is added to only the overlapping zones during laser irradiation, i.e., the predetermined pixel lines on which changes in Vth are predictable. By individually adding the same adjusting mechanism to all the lines, the display evenness can be adjusted to the level invisible in practical use for occurrence of the change in Vth on uncertain lines such as occurrence of “laser mis-shot”.

In this embodiment, the explanation was made of the case where polysilicon was made by the excimer laser which can easily produce the polysilicon with a larger grain size. But the same effect can be obtained also in the case where the polysilicon was made by the YAG laser. Further, as an example of the transmissive liquid crystal display device, the liquid crystal display device with the pixel electrodes of ITO was explained. But this invention can be widely applied to the reflective liquid crystal display device with a reflecting electrode of Al, semi-transmissive liquid crystal display device with both properties and further an organic EL display device using thin film transistors of a silicon film crystallized by the same laser described above. In the case of the organic EL, in principle, unevenness is greatly visually recognized in the characteristics of the transistors within the pixels so that the greater effect can be obtained.

As described above, in accordance with the invention according to the second embodiment of this invention, the panel is arranged so that the overlapping zones during laser irradiation in laser anneal are in parallel to source lines, thereby making it difficult visually recognize the unevenness due to the changes in the threshold values of the thin film transistors within each of the overlapping zones.

By the application of the first and second embodiments, transistors with different Vth values and driving capabilities can be arranged without using a CD mask through the overlapping of laser irradiation.

What is claimed is:

1. A display device comprising:
a plurality of pixel lines each with a plurality of pixels;
a pixel array consisting of said plurality of pixel lines;
pixel transistors for driving said plurality of pixels; and
a driving circuit for driving said plurality of pixel transistors, wherein:
said plurality of pixel transistors include a plurality of predetermined pixel transistors;
said driving circuit includes a first driving circuit for driving said predetermined pixel transistors, and a second driving circuit for driving other pixel transistors than said predetermined pixel transistors; and
a difference in a threshold voltage among the respective predetermined pixel transistors ranges from 0.1 V to 0.5 V inclusive, and a difference in a threshold voltage between said predetermined pixel transistors and the other pixel transistors than said predetermined pixel transistors ranges from 0.5 V to 1.5 V inclusive.

2. The display device according to claim 1, wherein
said plurality of pixel lines include a plurality of predetermined lines each with pixels driven by said predetermined pixel transistors.

3. The display device according to claim 2, wherein
said predetermined lines are in parallel to source lines.

4. The display device according to claim 2, wherein
said predetermined lines are in parallel to gate lines.

5. The display device according to claim 2, wherein
the number of said predetermined pixel lines is three or more, and said predetermined pixel lines are periodically located on said pixel array.

6. The display device according to claim 1, characterized in that an output impedance of said first driving circuit is different from that of said second driving circuit.

7. the display device according to claim 6, wherein
the routing distance of an internal wiring of said first driving circuit or of a wiring from said first driving circuit to said predetermined pixel transistors is different from that of an internal wiring of said second driving circuit or of a wiring from said second driving circuit to the other transistors than said predetermined pixel transistors.

8. The display device according to claim 6, wherein
an internal wiring of said first driving circuit or of a wiring from said first driving circuit to said predetermined pixel transistors is made of a different material from that of an internal wiring of said second driving circuit or of a wiring from said second driving circuit to the other transistors than said predetermined pixel transistors.

9. The display device according to claim 1, wherein
a driving voltage for said pixel transistors is adjustable.

10. The display device according to claim 1, wherein
the shape or material of each of said predetermined pixel transistors is different from that of the pixel transistors other than said predetermined pixel transistors.

11. A method for manufacturing a display device, comprising:
annealing beam irradiated regions by shifting irradiation of a laser beam onto a substrate; and
repeating the irradiation of the laser beam a plurality of number of times so as to anneal an interior plane of said substrate with an overlapping zone between said beam irradiated regions thereby to form a pixel transistors and other thin film transistors so that a predetermined pixel transistor are located within the overlapping zone.
